(19) United States
(12) Patent Application Publication
(10) Pub. No.: US 2026/0150532 A1
(43) Pub. Date: May 28, 2026

(54) DISPLAY DEVICE

(71) Applicant: LG Display Co., Ltd., Seoul (KR)

(72) Inventors: Doyoung JUNG, Paju-si (KR); Yongchan PARK, Paju-si (KR); Sungsu HAN, Paju-si (KR)

(73) Assignee: LG Display Co., Ltd., Seoul (KR)

(21) Appl. No.: 19/323,303

(22) Filed: Sep. 9, 2025

(30) Foreign Application Priority Data
Nov. 22, 2024 (KR) 10-2024-0168244

(51) Int. Cl. H10K 59/126; G09G 3/3266; G09G 3/3291; H10K 59/121; H10K 59/131

(52) U.S. Cl. CPC H10K 59/126; G09G 3/3266; G09G 3/3291; H10K 59/1213; H10K 59/1216; H10K 59/131; G09G 2300/0426; G09G 2300/043; G09G 2300/0819; G09G 2330/021

(57) ABSTRACT

A display device can include a substrate, a first light shielding layer disposed on the substrate, a second light shielding layer disposed on the first light shielding layer, an active layer disposed on the second light shielding layer and including a semiconductor region of a first transistor, a gate layer including a gate electrode of the first transistor disposed on the active layer, a first source metal layer including a first hold line disposed on the gate layer and configured to supply a hold signal, a second source metal layer including a second hold line disposed on the first source metal layer and connected to the first hold line, and a light emitting element including a pixel electrode disposed on the second source metal layer.

### CROSS-REFERENCE TO RELATED APPLICATION

The present application claims priority to Korea Patent Application No. 10-2024-0168244, filed in the Republic of Korea on Nov. 22, 2024, the entire contents of which is hereby expressly incorporated by reference into the present application.

### BACKGROUND

### Field

The present disclosure relates to a display device.

### Discussion of the Related Art

As information society has developed, various demands on the display device for displaying an image are increasing, and various display devices such as a liquid crystal display (LCD), and an organic light emitting display (OLED) have been utilized.

The images displayed on the display device can be still images or moving images. If the images are moving images, the images can be various kinds such as sports images, game images, movies, and the like. The display device can include a plurality of pixels and a plurality of switching elements for driving the pixels.

### SUMMARY OF THE DISCLOSURE

The technical problems and limitations associated with the related art are addressed or overcome by the present disclosure that provides a display device in which some pixels can be sensed in real-time during the display-driving.

The technical problems and limitations to be addressed or overcome by the present disclosure are not limited to the above-mentioned technical problems, and other technical problems that are not mentioned will be inferred from the discussions of the embodiments provided below.

One or more embodiments of the present disclosure solve or address the above-described and other limitations, by providing a display device, including: a light emitting element configured to emit light; a first transistor configured to control a driving current flowing in the light emitting diode; a second transistor configured to supply a data voltage to a first node which is a gate electrode of the first transistor based on a first scan signal; a third transistor configured to supply an initialization voltage to a second node which is a source electrode of the first transistor based on a second scan signal; a fourth transistor configured to supply a hold signal to a third node based on the first scan signal; a fifth transistor electrically connecting a reference voltage line and the first node based on a voltage of the third node; and a sixth transistor electrically connecting the second node and a sensing line based on a voltage of the third node.

Another embodiment of the present disclosure provides a display device, including: a data line configured to supply a data voltage; a display driver configured to supply a data voltage to the data line; an initialization voltage line configured to supply an initialization voltage; a reference voltage line configured to supply a reference voltage; a light emitting diode configured to emit light during a driving interval which is one part of a plurality of frame periods; a sensing line configured to supply a sensing signal to the display driver during a sensing interval which is another part of the plurality of frame periods; a hold line configured to supply a hold signal; a first transistor configured to control a driving current flowing in the light emitting diode; a second transistor configured to electrically connect the data line and a first node which is a gate electrode of the first transistor based on a first scan signal; a third transistor electrically connecting the initial voltage line and a second node which is a source electrode of the first transistor based on a second scan signal; a fourth transistor electrically connecting the hold line and a third node based on the first scan signal; a fifth transistor electrically connecting the reference voltage line and the first node based on a voltage of the third node; a sixth transistor electrically connecting the second node and the sensing line based on a voltage of the third node; a first capacitor connected between the first node and the second node; and a second capacitor connected between the third node and the reference voltage line.

Other details of the embodiments of the present disclosure are included in the detailed description and the accompanying drawings.

The display device according to the embodiments of the present disclosure can sense a threshold voltage of a driving transistor of some pixel during the display-driving because the display device includes first to sixth transistors and first and second capacitors.

The display device according to the embodiments of the present disclosure can improve reliability of a display and reduce power consumption by sensing some pixel in real-time during the display-driving.

However, effects which can be obtained by the present disclosure are not limited to the aforementioned effects, and other technical effects not described above can be evidently understood by a person having ordinary skill in the art to which the present disclosure pertains from the following description.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a plan view illustrating a display device according to an embodiment of the present disclosure.

FIG. 2 is a block diagram illustrating a display device according to an embodiment of the present disclosure.

FIG. 3 is a diagram illustrating a connection relationship between a unit pixel and lines in a display device according to an embodiment of the present disclosure.

FIG. 4 is a diagram illustrating a connection relationship between pixels and lines in a display device according to an embodiment of the present disclosure.

FIG. 5 is a circuit diagram illustrating a circuit of a display device according to an embodiment of the present disclosure.

FIG. 6 is a waveform diagram illustrating signals input to a pixel at a sensing interval in a display device according to an embodiment of the present disclosure.

FIG. 7 is a waveform diagram illustrating signals input to a pixel at a driving interval in a display device according to an embodiment of the present disclosure.

FIG. 8 is a layout diagram illustrating a pixel of a display device according to an embodiment of the present disclosure.

FIG. 9 is a diagram illustrating one layer of the layout diagram in FIG. 8.

FIG. 10 is a diagram illustrating another layer of the layout diagram in FIG. 8.

FIG. 11 is a diagram illustrating still another layer of the layout diagram in FIG. 8.

FIG. 12 is a diagram illustrating still another layer of the layout diagram in FIG. 8.

FIG. 13 is a cross-sectional view taken along I-I′ line of FIGS. 8 to 11.

FIG. 14 is a cross-sectional view taken along II-II′ line of FIGS. 8 to 11.

FIG. 15 is a cross-sectional view taken along III-III′ line of FIGS. 8 to 11.

### DETAILED DESCRIPTION OF THE EMBODIMENTS

Hereinafter, embodiments of the present disclosure will be described with reference to the drawings. In this specification, when it is mentioned that a component (or, an area, a layer, a part, etc.) is referred to as being “on”, “connected to” or “combined to” another component, this means that the component can be directly on, connected to, or combined to the other component or a third component therebetween can be present.

Like reference numerals refer to like elements. Additionally, in the drawings, the thicknesses, proportions, and dimensions of components are exaggerated for effective description. “And/or” includes all of one or more combinations defined by related components.

It will be understood that the terms “first” and “second” are used herein to describe various components but these components should not be limited by these terms. The above terms are used only to distinguish one component from another and may not define order or sequence. For example, a first component can be referred to as a second component and vice versa without departing from the scope of the disclosure. The singular expressions include plural expressions unless the context clearly dictates otherwise.

In addition, terms such as “below”, “the lower side”, “on”, and “the upper side” are used to describe a relationship of configurations shown in the drawing. The terms are described as a relative concept based on a direction shown in the drawing. Further, the term “can” fully encompasses all the meanings and coverages of the term “may” and vice versa.

In various embodiments of the disclosure, the term such as “include,” “comprise,” “including,” or “comprising,” specifies a property, a fixed number, a step, a process, an element and/or a component, or a combination thereof, but does not exclude presence or addition of other properties, fixed numbers, steps, processes, elements and/or components, or a combination thereof.

Now, a display device according to various embodiments of the present disclosure will be described referring to the drawings. All the components of each display device/apparatus according to all embodiments of the present disclosure are operatively coupled and configured.

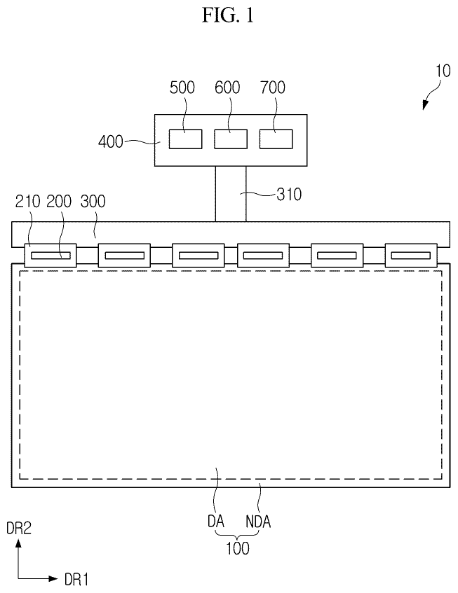

FIG. 1 is a plan view illustrating a display device according to an embodiment of the present disclosure.

Referring to FIG. 1, a display device 10 can be applied to a portable electronic device such as a mobile phone, a smart phone, a tablet personal computer, a mobile communication terminal, an electronic organizer, an e-book reader, a portable multimedia player (PMP), a navigation apparatus, an ultra-mobile PC (UMPC), and the like. For example, the display device 10 according to the present embodiment can be applied as a display unit of a television, a notebook computer, a monitor, a billboard, an Internet of things (IoT) device, and the like. As another example, the display device 10 according to the present embodiment can be applied to various wearable devices, for example, such as smart watches, watch phones, glass-like displays, head-mounted displays (HMDs), and the like.

The display device 10 can include a display panel 100, a display driver 200, a flexible film 210, a source circuit board 300, a flexible cable 310, a control circuit board 400, a timing controller 500, a power supply unit 600, and a memory 700.

The display panel 100 can include a display region DA (or display area or active area) and a non-display region NDA (or non-display area or non-active area). The display region DA can include a plurality of pixels configured to display an image. Each of the plurality of pixels can emit light from an emission region or an opening region. For example, the display region DA can include a pixel circuit including switching elements, a pixel defining layer defining the emission region, and a self-light emitting element.

For example, the self-light emitting element can include at least one among an organic light emitting diode including an organic light emitting layer, a quantum-dot (QD) light emitting diode (LED) including a quantum-dot light emitting layer, an inorganic light emitting diode (LED) including an inorganic semiconductor, and a micro-light emitting diode (LED) or a nano-light emitting diode (LED), but is not limited thereto.

The display driver 200 can supply a data voltage to a data line of the display panel 100. The display driver 200 can be electrically connected to a data line of the display panel 100 through a pad part of the display panel 100 and the flexible film 210. The display driver 200 can be formed as an integrated circuit (IC). For example, the display driver 200 can be attached to one surface of the flexible film 210 in a chip-on-film (COF) manner. The flexible film 210 can include lines electrically connecting the display driver 200 and the display panel 100. One side of the flexible film 210 can be electrically connected to the pad part of the display panel 100, and the other side of the flexible film 210 can be electrically connected to a source circuit board 300.

The source circuit board 300 can electrically connect the control circuit board 400 and the flexible film 210. The source circuit board 300 can be a printed circuit board which includes lines electrically connecting the display driver 200 and the other devices. The source circuit board 300 can be electrically connected to the control circuit board 400 through the flexible cable 310. For example, the flexible cable 310 can be a flexible flat cable (FFC), but is not limited thereto.

The control circuit board 400 can be a printed circuit board which mounts the timing controller 500, the power supply unit 600, and the memory 700 therein. The control circuit board 400 can mount control components and various electronic devices therein, without limitation to the illustration of FIG. 1.

The timing controller 500 can be attached to one surface of the control circuit board 400. The timing controller 500 can control the operation timing of the display driver 200 by transmitting digital video data to the display driver 200. The timing controller 500 can supply the digital video data compensated based on the threshold voltage information received from the memory to the display driver 200.

The power supply unit 600 can generate the power supply voltage and supply the power supply voltage to the display panel 100. Here, the power supply voltage can include a driving voltage EVDD, a low potential voltage EVSS, an initialization voltage Vint, a reference voltage Vref, and a bias voltage Vbias, but is not limited thereto.

The memory 700 can store sensing information of the pixels. For example, the memory 700 can store information on a threshold voltage of the transistor received from the display driver 200, and supply the threshold voltage information to the timing controller 500.

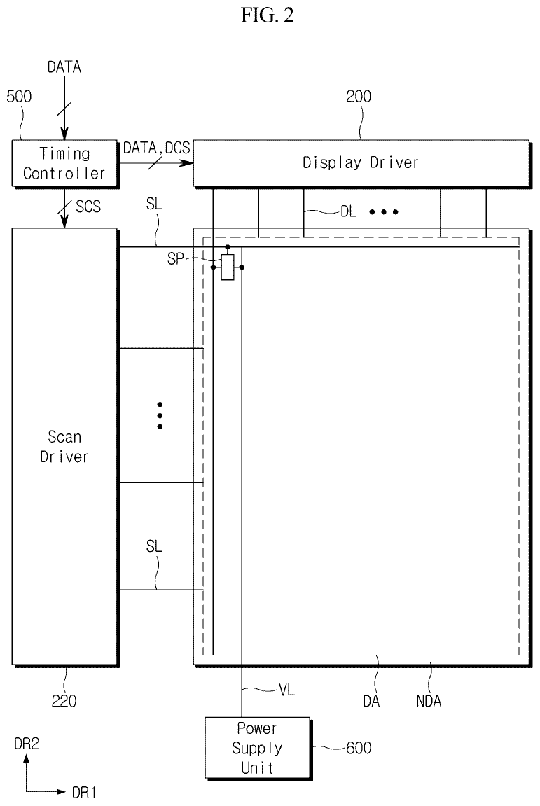

FIG. 2 is a block diagram illustrating the display device according to an embodiment of the present disclosure.

Referring to FIG. 2, the display panel 100 can include a display region DA and a non-display region NDA. The display region DA can include a plurality of pixels SP, a power line connected to the pixel SP, a scan line SL, and a data line DL.

Each of the pixels SP can be connected to the scan line SL, the data line DL, and a power line VL. Each of the pixels SP can include a transistor, a light emitting diode, and a capacitor.

The scan lines SL can extend in a first direction DR1, and can be spaced from each other in a second direction DR2 intersecting the first direction DR1. The scan lines SL can sequentially supply the scan signals to the plurality of pixels SP.

The data lines DL can extend in the second direction DR2, and can be spaced from each other in the first direction DR1. The data lines DL can supply the data voltage to the pixels SP. The data voltage can determine luminance of the pixel SP.

The power supply lines VL can extend in the second direction DR2, and can be spaced apart from each other in the first direction. The power supply lines VL can supply a power supply voltage to the plurality of pixels SP. The power supply voltage can include a driving voltage EVDD, a low potential voltage EVSS, an initialization voltage Vint, a reference voltage Vref, and a bias voltage Vbias, but is not limited thereto.

The scan driver 220 can include a plurality of transistors, and can generate scan signals based on a scan control signal SCS. The scan driver 220 can shift a scan signal using a shift register, and can sequentially supply the shifted scan signals to the scan lines. The scan signals of the scan driver 220 can select the pixels SP to which the data voltage is supplied, and the selected pixels SP can receive the data voltage through the data lines DL. The scan driver 220 can be disposed on one side or both sides of the non-display region DNA in a Gate-In-Panel (GIP) manner.

The timing controller 500 can receive digital video data DATA and timing signals from a display driving system or a graphic device. The timing controller 500 can generate the data control signal DCS based on the timing signals. The timing controller 500 can supply the digital video data DATA and the data control signal DCS to the data driver 200 to control an operation timing of the display driver 200. The display driver 200 can convert the digital video data DATA into the analog data voltages and supply the analog data voltages to the data lines DL. The timing controller 500 can generate the scan control signal SCS based on the timing signals. The timing controller 500 can supply the scan control signal SCS to the scan driver 220 to control an operation timing of the scan driver 220.

The power supply unit 600 can supply a power supply voltage to the power supply lines VL. The power supply voltage can include a driving voltage EVDD, a low potential voltage EVSS, an initialization voltage Vint, a reference voltage Vref, and a bias voltage Vbias, but is not limited thereto. The power supply unit 600 can generate the driving voltage EVDD and supply the driving voltage EVDD to a driving voltage line, generate the initialization voltage Vint and supply the initialization voltage Vint to an initialization voltage line, generate the bias voltage Vbias and supply the bias voltage Vbias to the bias voltage line, generate the reference voltage Vref and supply the reference voltage Vref to a reference voltage line, and generate the low potential voltage EVSS and supply the low potential voltage EVSS to the low potential line.

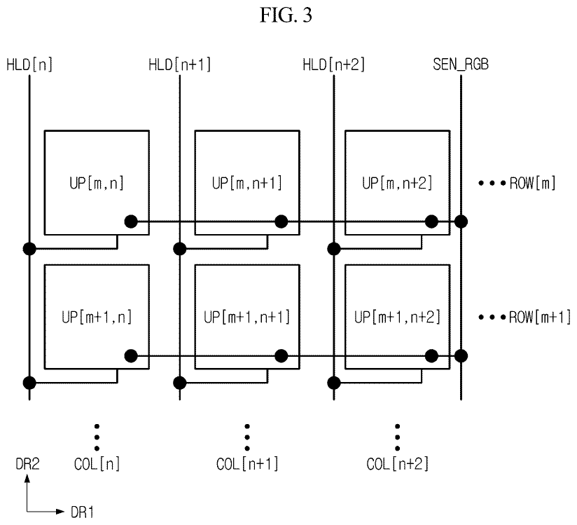

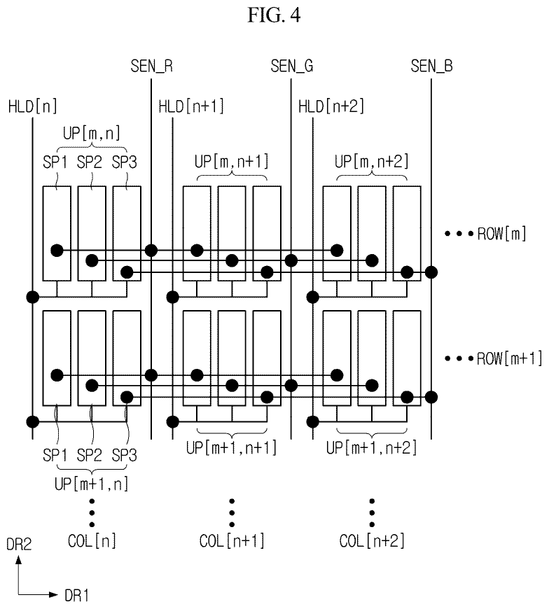

FIG. 3 is a diagram illustrating a connection relationship between a unit pixel and lines in the display device according to an embodiment of the present disclosure, and FIG. 4 is a diagram illustrating a connection relationship between the pixels and lines in the display device according to an embodiment of the present disclosure.

Referring to FIGS. 3 and 4, the unit pixel UP can be disposed along a plurality of rows ROW and a plurality of columns COL. For example, the unit pixel UP can be disposed along an m-th row ROW[m] and an (m+1)th row ROW[m+1] (m is an integer greater than 1), and an n-th column COL[n], an (n+1)th column COL[n+1], and an (n+2)th column COL[n+2] (n is an integer greater than 1). One unit pixel UP can include a plurality of pixels SP, each of which emits light of a different color. For example, one unit pixel UP can include a first pixel SP1 configured to emit red light, a second pixel SP2 configured to emit green light, and a third pixel SP3 configured to emit blue light.

A plurality of hold lines HLD can extend in the second direction DR2, and can be spaced apart from each other in the first direction DR1. An n-th hold line HLD[n] can supply a hold signal to the unit pixels UP[m, n] and UP[m+1, n] disposed in the n-th column COL[n]. Here, the hold signal can select the unit pixels UP desired to be sensed. For example, when the hold signal is applied, the display driver 200 can sense the threshold voltage of the driving transistor of the corresponding unit pixel UP. When the hold signal is not applied, the display driver 200 can drive such that the corresponding unit pixel UP emits light. The display driver 200 can select a few pixels SP during the display-driving, and can sense a threshold voltage of the first transistor T1. Therefore, the display device 100 can emit light by driving most of the pixels SP, and sense some pixels SP in real-time during the display-driving by sensing a few pixels SP which may not be visible to the eyes of the viewers.

An (N+1)th hold line HLD[n+1] can supply a hold signal to the unit pixels UP[m, n+1] and UP[m+1, n+1] disposed in the (n+1)th column COL[n+1]. An (n+2)th hold line HLD[n+1] can supply a hold signal to unit pixels UP[m, n+2] and UP[m+1, n+2] disposed in the (n+2)th column COL[n+2]. Here, N and n can be real numbers such as integers.

In FIG. 3, the plurality of sensing lines SEN_RGB can extend in the second direction DR2, and can be spaced apart from each other in the first direction DR1. One sensing line SEN_RGB can receive sensing signals from the unit pixels UP[m, n], UP[m, n+1], UP[m, n+2], UP[m+1, n], UP[m+1, n+1], and UP[m+1, n+2] disposed in the n-th, (n+1)th, and (n+2)th columns COL[n], COL[n+1], and COL[n+2]. The sensing line SEN_RGB can supply the sensing signal to the display driver 200, and can recognize a change amount of a threshold voltage of the driving transistor by receiving the sensing signal. In FIG. 3, the sensing line SEN_RGB can be electrically connected to the unit pixels UP disposed in three columns COL, however, a quantity of the columns of the unit pixels UP connected to the sensing line SEN_RGB is not limited thereto. The sensing line SEN_RGB can include a red sensing line SEN_R, a green sensing line SEN_G, and a blue sensing line SEN_B.

In FIG. 4, each of the red sensing line SEN_R, the green sensing line SEN_G, and the blue sensing line SEN_B can be electrically connected to the pixels SP which emit light in the same color. The red sensing line SEN_R can receive the sensing signal from a first pixel SP1 of each of the unit pixels UP[m, n], UP[m, n+1], UP[m, n+2], UP[m+1, n], UP[m+1, n+1], and UP[m+1, n+2]), respectively. The green sensing line SEN_G can receive the sensing signal from a second pixel SP2 of each of the unit pixels UP[m, n], UP[m, n+1], UP[m, n+2], UP[m+1, n], UP[m+1, n+1], and UP[m+1, n+2]. The blue sensing line SEN_B can receive the sensing signal from a third pixel SP3 of each of the unit pixels UP[m, n], UP[m, n+1], UP[m, n+2], UP[m+1, n], UP[m+1, n+1], and UP[m+1, n+2].

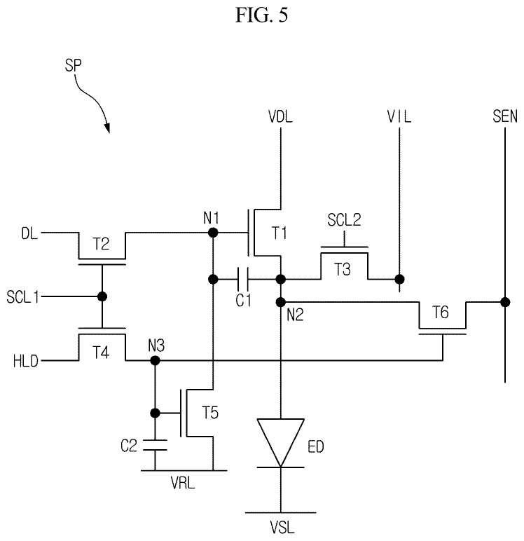

FIG. 5 is a circuit diagram illustrating the circuit of the display device according to an embodiment of the present disclosure.

Referring to FIG. 5, the pixel SP can be connected to a first scan line SCL1, a second scan line SCL2, a hold line HLD, a data line DL, a reference voltage line VRL, a driving voltage line VDL, an initialization voltage line VIL, a sensing line SEN, and a low potential line VSL.

The pixel SP can include a pixel circuit and a light emitting diode ED. The pixel circuit can include first to sixth transistors T1, T2, T3, T4, T5, and T6, and first and second capacitors C1 and C2.

The first transistor T1 can include a gate electrode, a drain electrode, and a source electrode. The first transistor T1 can control a drain-source current Ids (or a driving current) according to a data voltage applied to the gate electrode. The driving current Ids flowing through a channel of the first transistor T1 can be proportional to a square of a difference between a gate-source voltage Vgs of the first transistor T1 and the threshold voltage Vth. (Ids=k×(Vgs−Vth)²) Here, k means a proportional coefficient determined according to a structure and a physical characteristic of the first transistor T1, Vgs means the gate-source voltage of the first transistor T1, and Vth means a threshold voltage of the first transistor T1. The gate electrode of the first transistor T1 can be electrically connected to a first node N1, the drain electrode thereof can be electrically connected to the driving voltage line VDL, and the source electrode thereof can be electrically connected to a second node N2. The first transistor T1 can be a driving transistor of the pixel SP.

The light emitting diode ED can emit light by receiving the driving current Ids. An amount of emission or luminance of the light emitting diode ED can be proportional to a magnitude of the driving current Ids. The light emitting diode ED can be an organic light emitting diode which includes a first electrode, a second electrode, and an organic light emitting layer disposed between the first electrode and the second electrode, however, kinds of the light emitting diode is not limited thereto.

The first electrode of the light emitting diode ED can be electrically connected to the second node N2. The first electrode of the light emitting diode ED can be electrically connected to the source electrode of the first transistor T1, a drain electrode of a third transistor T3, and a drain electrode of a sixth transistor T6 through the second node N2. Here, the first electrode of the light emitting diode ED can be an anode electrode, or a pixel electrode. The second electrode of the light emitting diode ED can be electrically connected to the low potential line VSL, and can receive the low potential voltage EVSS from the low potential line VSL. Here, the second electrode of the light emitting diode ED can be a cathode electrode, or a common electrode.

The second electrode T2 can be turned on by a first scan signal of the first scan line SCL1, and can electrically connect the data line DL and the first node N1, which is the gate electrode of the first transistor T1. The second electrode T2 can supply the data voltage to the first node N1 as the second electrode T2 is turned on based on the first scan signal. A gate electrode of the second transistor T2 can be electrically connected to the first scan line SCL1, a drain electrode thereof can be electrically connected to the data line DL, and a source electrode thereof can be electrically connected to the first node N1.

The third transistor T3 can be turned on by the second scan signal of the second scan line SCL2, and can electrically connect the second node N2, which is the source electrode of the first transistor T1, and the initialization voltage line VIL. The third transistor T3 is turned on based on the second scan signal, therefore, the third transistor T3 can discharge the first electrode of the light emitting diode ED to as low as the initialization voltage Vint. A gate electrode of the third transistor T3 can be electrically connected to the second scan line SCL2, a drain electrode thereof can be electrically connected to the second node N2, and a source electrode thereof can be electrically connected to the initialization voltage line VIL.

A fourth transistor T4 can be turned on by the first scan signal of the first scan line SCL1, and can electrically connect the hold line HDL and a third node N3, which is a first electrode of the second capacitor C2. The fourth transistor T4 can charge the hold signal to the second capacitor C2 as the fourth transistor T4 is turned on based on the first scan signal. The hold signal charged to the third node N3 can be supplied to each gate electrode of the fifth and sixth transistors T5 and T6. A gate electrode of the fourth transistor T4 can be electrically connected to the first scan line SCL1, a drain electrode thereof can be electrically connected to the hold line HLD, and a source electrode thereof can be connected to the third node N3.

A fifth transistor T5 can be turned on by a voltage of the third node N3, and can electrically connect the reference voltage line VRL and the first node N1, which is the gate electrode of the first transistor T1. The fifth transistor T5 can supply the reference voltage Vref to the first node N1 as the fifth transistor T5 is turned on based on the voltage of the third node N3. A gate electrode of the fifth transistor T5 can be electrically connected to the third node N3, a drain electrode thereof can be electrically connected to the reference voltage line VRL, and a source electrode thereof can be electrically connected to the first node N1.

A sixth transistor T6 can be turned on by the voltage of the third node N3, and can electrically connect the second node, which is the first electrode of the light emitting diode ED, and the sensing line SEN. The sixth transistor T6 can supply the sensing signal to the sensing line SEN as the sixth transistor is turned on based on the voltage of the third node N3. A gate electrode of the sixth transistor T6 can be electrically connected to the third node N3, a drain electrode thereof can be electrically connected to the second node N2, and a source electrode thereof can be electrically connected to the sensing line SEN.

The first to sixth transistors T1, T2, T3, T4, T5, and T6 can include an active layer based on an oxide. The first to sixth transistors T1, T2, T3, T4, T5, and T6 can correspond to n-type transistors, and can output a current introduced into the drain electrode to the source electrode based on a gate high voltage VGH applied to the gate electrode. The active layer based on the oxide can have a relatively small S-factor, can increase a constant current driving region in a low grayscale region, and can improve low grayscale expression.

As another example, at least one among the first to sixth transistors T1, T2, T3, T4, T5, and T6 can include an active layer formed of the Low Temperature Polycrystalline Silicon (LTPS). At least one among the first to sixth transistors T1, T2, T3, T4, T5, and T6 can correspond to a p-type transistor, and can output a current introduced into the source electrode to the drain electrode based on a gate low voltage VGL applied to the gate electrode.

The first capacitor C1 can be electrically connected between the first node, which is the gate electrode of the first transistor T1 and the second node N2, which is the source electrode of the first transistor T1. For example, a first electrode of the first capacitor C1 is electrically connected to the first node N1, and the second electrode of the first capacitor C1 is electrically connected to the second node N2, thereby becoming able to maintain a potential difference between the gate electrode and the source electrode of the first transistor T1.

The second capacitor C2 can be electrically connected between the third node and the reference voltage line VRL. For example, the first electrode of the second capacitor C2 is electrically connected to the third node N3, and the second electrode of the second capacitor C2 is electrically connected to the reference voltage line VRL, thereby becoming able to maintain a potential difference between the third node N3 and the reference voltage line VRL.

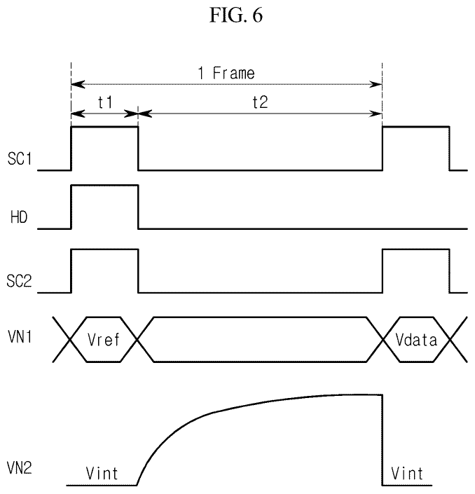

FIG. 6 is a waveform diagram illustrating signals input to the pixel at a sensing interval in the display device according to an embodiment of the present disclosure.

Referring to FIG. 6, the pixel SP can be connected to the first scan line SCL1, the second scan line SCL2, the hold line HLD, the data line DL, the reference voltage line VRL, the driving voltage line VDL, the initialization voltage line VIL, the sensing line SEN, and the low potential line VSL. The pixel SP can include the first to sixth transistors T1, T2, T3, T4, T5, and T6, the first and second capacitors C1 and C2, and the light emitting diode ED. The display driver 200 can receive the sensing signal at a sensing interval and can recognize a change amount of the threshold voltage of the first transistor T1.

The first scan line SCL1 can supply the first scan signal SC1 in a high level in a first period t1 of one frame period. The hold line HLD can supply the hold signal HD in a high level in the first period t1 of the one frame period. The fourth transistor T4 can be turned on in the first period t1, and the hold line HLD can supply the hold signal HD in a high level to the third node N3. The hold signal HD in a high level can be charged to the third node N3, which is the first electrode of the second capacitor C2.

Each of the fifth and sixth transistors T5 and T6 can be turned on based on the voltage of the third node N3 in the first and second periods t1 and t2 of the one frame period. The fifth transistor T5 can be turned on in the first and second periods t1 and t2 of the one frame period and can supply the reference voltage Vref to the first node N1, which is the gate electrode of the first transistor T1. Therefore, a voltage VN1 of the first node N1 can correspond to the reference voltage Vref in the first and second periods t1 and t2. The sixth transistor T6 can be turned on in the first and second periods t1 and t2 of the one frame period, and can electrically connect the second node N2, which is the source electrode of the first transistor T1, and the sensing line SEN.

The second scan line SCL2 can supply the second scan signal SC2 in a high level in the first period t1 of the one frame period. The third transistor T3 can be turned on in the first period t1, and the second node N2 which is the source electrode of the first transistor T1 can be discharged to as low as the initialization voltage Vint. Therefore, a voltage VN2 of the second node N2 can correspond to the initialization voltage Vint in the first period t1.

In the first period t1, as the gate electrode of the first transistor T1 receives the reference voltage Vref, and the source electrode of the first transistor T1 receives the initialization voltage Vint, the gate-source voltage Vgs of the first transistor T1 can become greater than the threshold voltage Vth of the first transistor T1, and the first transistor T1 can be turned on in the second period t2, thereby the drain-source current Ids can flow in the first transistor T1. The more the drain-source current Ids flows in the second period t2, the more the voltage VN2 of the second node N2 can increase. The voltage VN2 of the second node N2 can increase until the gate-source voltage Vgs of the first transistor T1 becomes equal to the threshold voltage Vth. When the gate-source voltage Vgs becomes equal to the threshold voltage Vth, the first transistor T1 can be turned off, and the drain-source current Ids may not flow therein anymore. Therefore, when there is no change in the threshold voltage Vth, the voltage VN2 of the second node N2 can become relatively higher, and when the threshold voltage Vth increases, the voltage VN2 of the second node N2 can become relatively low.

As the sixth transistor T6 is turned on, the drain-source current Ids flowing in the first transistor T1 can flow to the sensing line SEN. Here, when the sixth transistor T6 is turned on, an internal resistance of the sixth transistor T6 can be smaller than an internal resistance of the light emitting diode ED, and the drain-source current Ids can all flow to the sensing line SEN. The sixth transistor T6 can supply the voltage VN2 of the second node N2 to the sensing line SEN as a sensing signal, and the display driver 200 can recognize a change amount of the threshold voltage Vth of the first transistor T1 according to a size of the sensing signal.

The pixel SP may not emit light at the sensing interval. The hold signal HD can select a unit pixel UP desired to be sensed. When the hold signal HD is applied, the display driver 200 can sense the threshold voltage of the first transistor T1 of the corresponding unit pixel UP. When the hold signal HD is not applied, the display driver 200 can drive such that the corresponding unit pixel UP emits light. The display driver 200 can select a few pixels SP during the display-driving and sense the threshold voltage of the first transistor T1. Therefore, the display device 10 can emit light by driving most of the pixels SP, and can sense some pixels SP in real-time during the display-driving by sensing a few pixels SP which may not be visible to eyes of viewers.

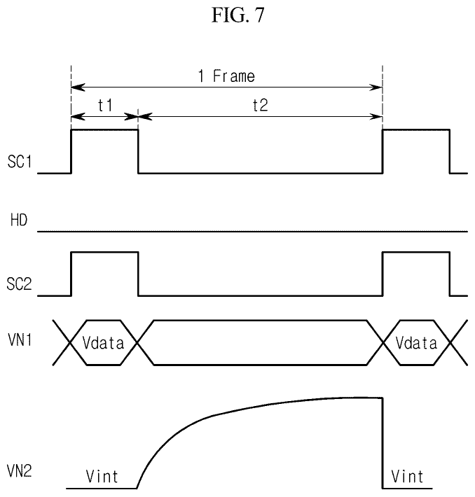

FIG. 7 is a waveform diagram illustrating signals input to the pixel at a driving interval in the display device according to an embodiment of the present disclosure.

Referring to FIG. 7, the first scan line SCL1 can supply the first scan signal SC1 in a high level in the first period t1 of the one frame period. The first scan line SCL1 can supply the first scan signal SC1 in a low level in the second period t2 of the one frame period. The hold line HLD can supply the hold signal HD in a low level in the first and second periods t1 and t2 of the one frame period. The fourth transistor T4 can be turned on in the first period t1, and the hold line HLD can supply the hold signal HD in a low level to the third node N3. Therefore, each of the fifth and sixth transistors T5 and T6 can be turned off based on a voltage of the third node N3 in the first and second periods t1 and t2 of the one frame period.

The second scan line SCL2 can supply the second scan signal SC2 in a high level in the first period t1 of the one frame period. The second scan line SCL2 can supply the second scan signal SC2 in a low level in the second period t2 of the one frame period.

The second transistor T2 can be turned on in the first period t1 of the one frame period and can supply the data voltage Vdata to the first node N1, which is the gate electrode of the first transistor T1. Therefore, the voltage VN1 of the first node N1 can correspond to the data voltage Vdata in the first period t1. The third transistor T3 can be turned on in the first period t1, and the second node N2 which is the source electrode of the first transistor T1 can be discharged to as low as the initialization voltage Vint. Therefore, the voltage VN2 of the second node N2 can correspond to the initialization voltage Vint in the first period t1. Therefore, as the gate electrode of the first transistor T1 receives the data voltage Vdata and the source electrode of the first transistor T1 receives the initialization voltage Vint in the first period t1, the gate-source voltage Vgs of the first transistor T1 can become greater than the threshold voltage Vth of the first transistor T1.

The first transistor T1 can be turned on in the second period t2, and the drain-source current Ids can flow in the first transistor T1. The more the drain-source current Ids flows in the second period t2, the more the voltage VN2 of the second node N2 can increase. The voltage VN2 of the second node N2 can increase until the gate-source voltage Vgs of the first transistor T1 becomes equal to the threshold voltage Vth. When the gate-source voltage Vgs becomes equal to the threshold voltage Vth, the first transistor T1 can be turned off and the drain-source current Ids may not flow therein anymore.

The light emitting diode ED can emit light by receiving the drain-source current Ids of the first transistor T1. An amount of the light emission or luminance of the light emitting diode ED can be proportional to a magnitude of the driving current Isd determined according to a magnitude of the data voltage Vdata. The voltage VN2 of the second node N2 can increase according to the magnitude of the data voltage Vdata, and can determine the luminance of the light emitting diode ED.

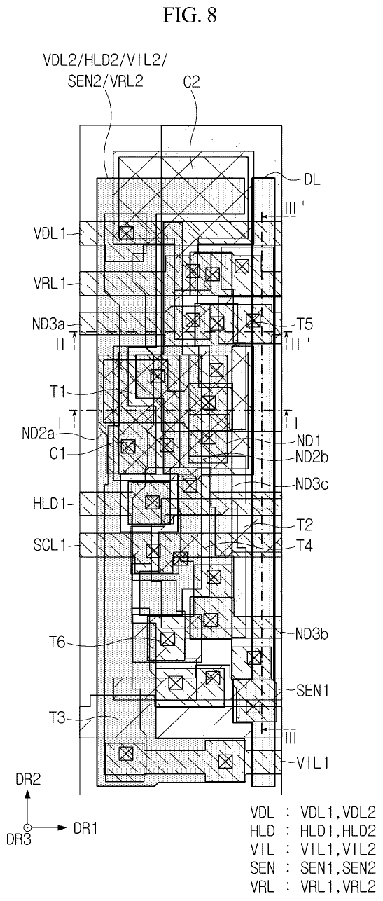

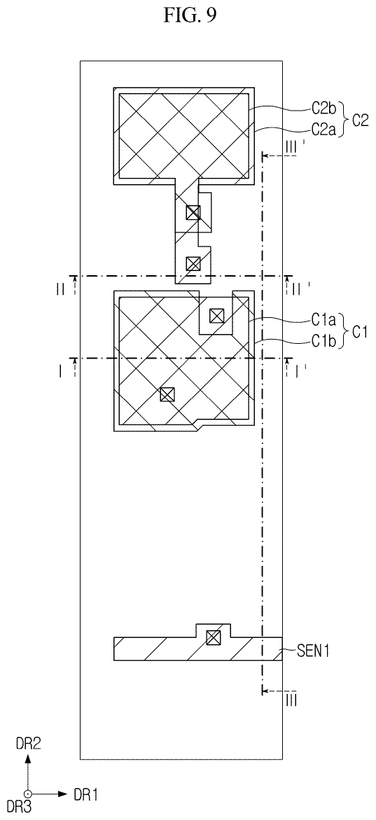

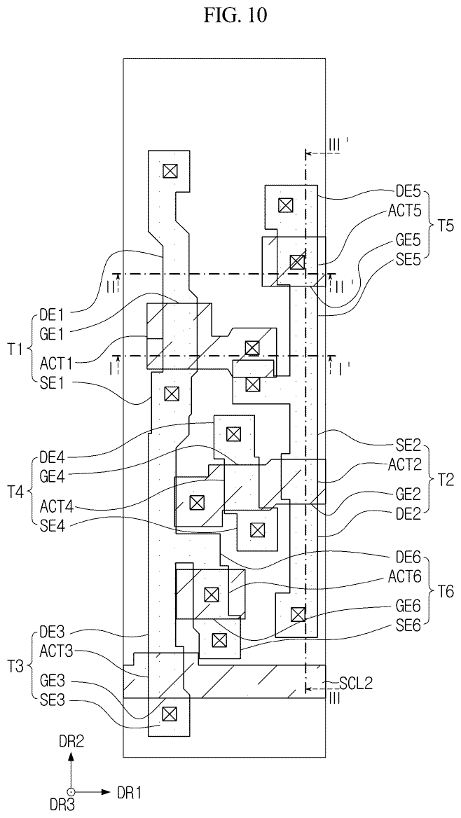

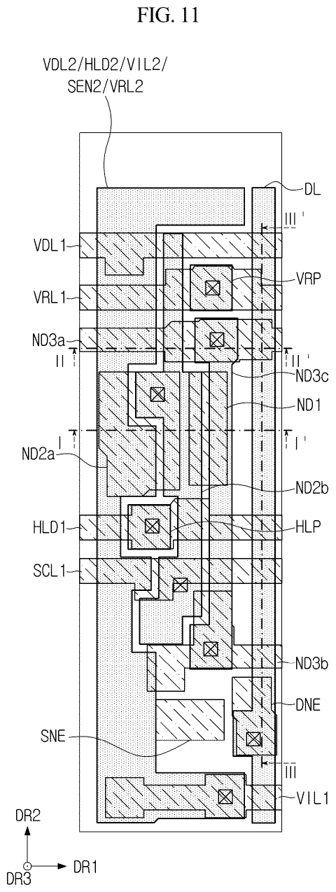

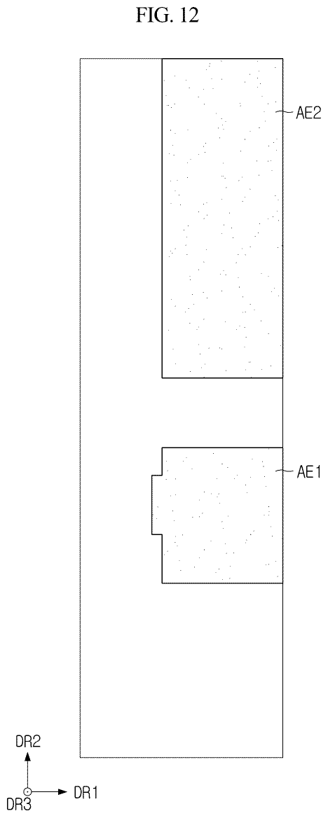

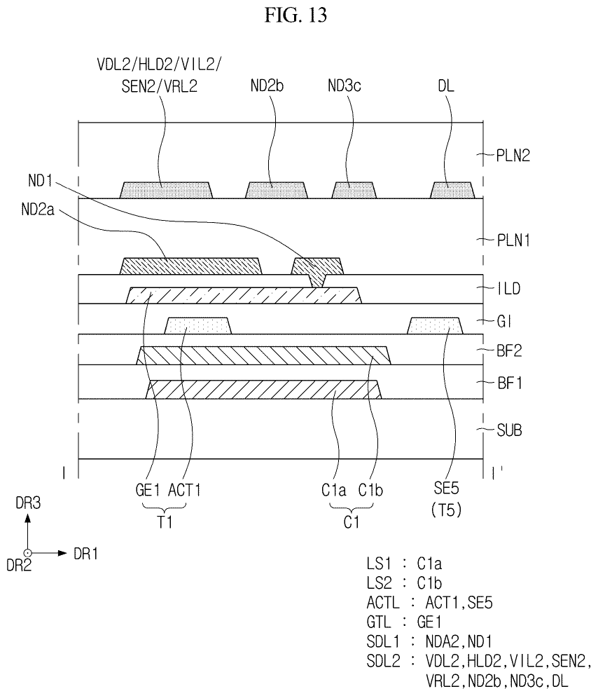

FIG. 8 is a layout diagram illustrating the pixel of the display device according to an embodiment of the present disclosure. FIG. 9 is a diagram illustrating one layer of the layout diagram in FIG. 8, and illustrates a lamination structure of a first light shielding layer LS1 and a second light shielding layer LS2. FIG. 10 is a diagram illustrating another layer of the layout diagram in FIG. 8, and illustrates a lamination structure of an active layer ACTL and a gate layer GTL. FIG. 11 is a diagram illustrating still another layer of the layout diagram in FIG. 8, and illustrates a lamination structure of a first source metal layer SDL1 and a second source metal layer SDL2. FIG. 12 is a diagram illustrating still another layer of the layout diagram in FIG. 8, and illustrates a first pixel electrode AE1 and a second pixel electrode AE2. FIG. 13 is a cross-sectional view taken along I-I′ line of FIGS. 8 to 11, FIG. 14 is a cross-sectional view taken along II-II′ line of FIGS. 8 to 11, and FIG. 15 is a cross-sectional view taken along III-III′ line of FIGS. 8 to 11.

Referring to FIGS. 8 to 15, the plurality of pixels SP can be disposed in a plurality of rows and a plurality of columns. Each of the plurality of pixels SP can be connected to the first scan line SCL1, the second scan line SCL2, the hold line HLD, the data line DL, the reference voltage line VRL, the driving voltage line VDL, the initialization voltage line VIL, the sensing line SEN, and the low potential line VSL.

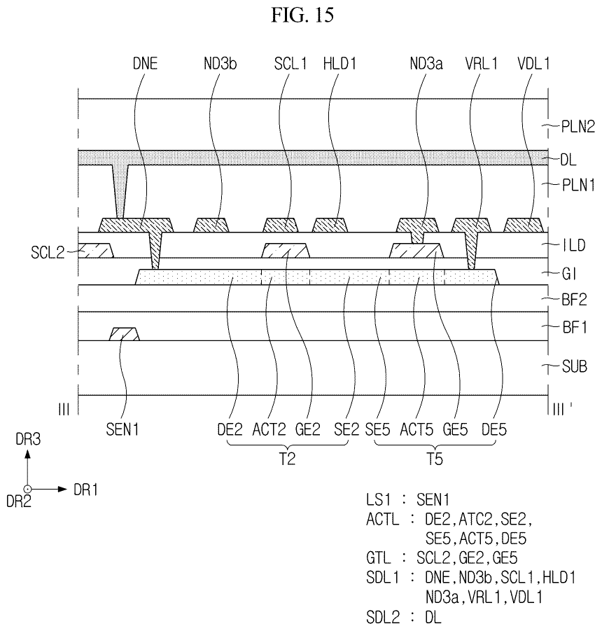

The driving voltage line VDL can include a first driving voltage line VDL1 and a second driving voltage line VDL2. In FIGS. 11 and 15, the first driving voltage line VDL1 can extend in the first direction DR1 in the first source metal layer SDL1. The first driving voltage line VDL1 can supply the driving voltage EVDD received from the second driving voltage line VDL2 to the pixel SP. The first driving voltage line VDL1 can be inserted into a contact hole penetrating an inter-layer insulation layer ILD and a gate insulation layer GI, and can be connected to a drain electrode DE1 of the first transistor T1. In FIGS. 11, 13, and 14, the second driving voltage line VDL2 can extend in a second direction in the second source metal layer SDL2. The second driving voltage line VDL2 can supply the driving voltage EVDD received from the power supply unit 600 to the first driving voltage line VDL1. The second driving voltage line VDL2 can be inserted into a contact hole penetrating a first protection layer PLN1 and can be connected to the first driving voltage line VDL1.

The second driving voltage line VDL2, a second hold line HLD2, a second initialization voltage line VIL2, a second sensing line SEN2, and a second reference voltage line VRL2 can be alternately disposed in the plurality of columns of the pixels SP. For example, the second driving voltage line VDL2 can be disposed in one column of the pixels SP, the second hold line HLD2 can be disposed in another column of the pixels SP, the second initialization voltage line VIL2 can be disposed in still another column of the pixels SP, the second sensing line SEN2 can be disposed in still another column of the pixels SP, and the second reference voltage line VRL2 can be disposed in still another column of the pixels SP. Therefore, one among the second driving voltage line VDL2, the second hold line HLD2, the second initialization voltage line VIL2, the second sensing line SEN2, and the second reference voltage line VRL2 can be disposed at a position illustrated in FIG. 11.

The hold line HLD can include a hold pattern HLP, and first and second hold lines HLD1 and HLD2. In FIG. 11, the hold pattern HLP can be disposed in the second source metal layer SDL2. The hold pattern HLP can be inserted into a contact hole penetrating the first protection layer PLN1 and can be connected to a first hold line HLD1. In FIGS. 11 and 15, the first hold line HLD1 can extend in the first direction DR1 in the first source metal layer SDL1. The first hold line HLD1 can supply the hold signal HD received from the second hold line HLD2 to the pixel SP. The first hold line HLD1 can be inserted into a contact hole penetrating the inter-layer insulation layer ILD and the gate insulation layer GI, and can be connected to a drain electrode DE4 of the fourth transistor T4. In FIGS. 11, 13 and 14, the second hold line HLD2 can extend in the second direction DR2 in the second source metal layer SDL2. The second hold line HLD2 can supply the hold signal HD received from the display driver 200 to the first hold line HLD1. The second hold line HLD2 can be inserted into a contact hole penetrating the first protection layer PLN1, and can be connected to the first hold line HLD1.

The initialization voltage line VIL can include the first and second initialization voltage lines VIL1 and VIL2. In FIG. 11, the first initialization voltage line VIL1 can extend in the first direction DR1 in the first source metal layer SDL1. The first initialization voltage line VIL1 can supply the initialization voltage Vint received from the second initialization voltage VIL2 to the pixel SP. The first initialization voltage line VIL1 can be inserted into a contact hole penetrating the inter-layer insulation layer ILD and the gate insulation layer GI, and can be connected to a source electrode SE3 of the third transistor T3. In FIGS. 11, 13 and 14, the second initialization voltage line VIL2 can extend in the second direction DR2 in the second source metal layer SDL2. The second initialization voltage line VIL2 can supply the initialization voltage Vint received from the power supply unit 600 to the first initialization voltage line VIL1. The second initialization voltage line VIL2 can be inserted into a contact hole penetrating the first protection layer PLN1, and can be connected to the first initialization voltage line VIL1.

The sensing line SEN can include first and second sensing lines SEN1 and SEN2. In FIGS. 9 and 15, a first sensing line SEN1 can extend in the first direction DR1 in the first light shielding layer LS1. The first sensing line SEN1 can supply the sensing signal received from the sixth transistor T6 to the second sensing line SEN2. The first sensing line SEN1 can be electrically connected to a source electrode SE6 of the sixth transistor T6 through a sensing connection electrode SNE disposed in the first source metal layer SDL1. One side of the sensing connection electrode SNE can be inserted into a contact hole penetrating the inter-layer insulation layer ILD, the gate insulation layer GI, a second buffer layer BF2, and a first buffer layer BF1 and can be connected to the first sensing line SEN1. The other side of the sensing connection electrode SNE can be inserted into a contact hole penetrating the inter-layer insulation layer ILD and the gate insulation layer GI, and can be connected to the source electrode SE6 of the sixth transistor T6. In FIGS. 11, 13 and 14, the second sensing line SEN2 can extend in the second direction DR2 in the second source metal layer SDL2. The second sensing line SEN2 can supply the sensing signal received from the first sensing line SEN1 to the display driver 200. The second sensing line SEN2 can be electrically connected to the first sensing line SEN1 through the sensing connection electrode SNE.

The reference voltage line VRL can include a reference pattern VRP, and first and second reference voltage lines VRL1 and VRL2. In FIG. 11, the reference pattern VRP can be disposed in the second source metal layer SDL2. The reference pattern VRP can be inserted into a contact hole penetrating the first protection layer PLN1 and can be connected to a first reference voltage line VRL1. In FIGS. 11 and 15, the first reference voltage line VRL1 can extend in the first direction DR1 in the first source metal layer SDL1. The first reference voltage line VRL1 can supply the reference voltage Vref received from the second reference voltage line VRL2 to the pixel SP. The first reference voltage line VRL1 can be inserted into a contact hole penetrating the inter-layer insulation layer ILD, the gate insulation layer GI, and the second buffer layer BF2, and can be connected to a second electrode C2b of the second capacitor C2. The first reference voltage line VRL1 can be inserted into a contact hole penetrating the inter-layer insulation layer ILD and the gate insulation layer GI, and can be connected to a drain electrode DE5 of the fifth transistor T5. In FIGS. 11, 13 and 14, the second reference voltage line VRL2 can extend in the second direction DR2 in the second source metal layer SDL2. The second reference voltage line VRL2 can supply the reference voltage EVDD received from the power supply unit 600 to the first reference voltage line VRL1. The second reference voltage line VRL2 can be inserted into a contact hole penetrating the first protection layer PLN1, and can be connected to the first reference voltage line VRL1.

In FIG. 10, the first transistor T1 can include a semiconductor region ACT1, the drain electrode DE1, a source electrode SE1, and a gate electrode GE1. The semiconductor region ACT1, the drain electrode DE1, and the source electrode SE1 of the first transistor T1 can be disposed in the active layer ACTL, and the gate electrode GE1 of the first transistor T1 can be disposed in the gate layer GTL. The gate electrode GE1 of the first transistor T1 can overlap the semiconductor region ACT1 of the first transistor T1. For example, the semiconductor region ACT1 of the first transistor T1 can include an oxide, and the drain electrode DE1 and the source electrode SE1 of the first transistor T1 can be n-type doped.

The gate electrode GE1 of the first transistor T1 can be electrically connected to a first electrode Cla of the first capacitor C1, a source electrode SE2 of the second transistor T2, and a source electrode SE5 of the fifth transistor T5 through a first node electrode ND1 disposed in the first source metal layer SDL1. Here, the first node electrode ND1 can correspond to the first node N1 in FIG. 5. In FIG. 13, the first node electrode ND1 can be inserted into a contact hole penetrating the inter-layer insulating layer ILD, and can be connected to the gate electrode GE1 of the first transistor T1. The first node electrode ND1 can be inserted into a contact hole penetrating the inter-layer insulating layer ILD and the gate insulation layer GI, and can be connected to the source electrode SE2 of the second transistor T2 and the source electrode SE5 of the fifth transistor T5. The first node electrode ND1 can be inserted into a contact hole penetrating the inter-layer insulating layer ILD, the gate insulation layer GI, the second buffer layer BF2, and the first buffer layer BF1, and can be connected to the first electrode Cla of the first capacitor C1.

The drain electrode DE1 of the first transistor T1 can receive the driving voltage EVDD from the first driving voltage line VDL1 disposed in the first source metal layer SDL1. The source electrode SE1 of the first transistor T1 can be integrally formed with a drain electrode DE3 of the third transistor T3 and a drain electrode DE6 of the sixth transistor T6. The source electrode SE1 of the first transistor T1 can be electrically connected to the second electrode Clb of the first capacitor C1 and a second portion ND2b of the second node electrode through a first portion ND2a of the second node electrode disposed in the first source metal layer SDL1. The second portion ND2b of the second node electrode can be connected to the first pixel electrode AE1 of the light emitting diode ED. The second portion ND2b of the second node electrode can supply the driving current flowing in the first transistor T1 to the first pixel electrode AE1 in FIG. 12. The first pixel electrode AE1 can be inserted into a contact hole penetrating a second protection layer PLN2, and can be in contact with the second portion ND2b of the second node electrode. The light emitting diode ED, which includes the first pixel electrode AE1, can emit light through a first light emitting region defined by a pixel defining layer.

In FIGS. 11 and 13, the first portion ND2a and the second portion ND2b of the second node electrode can correspond to the second node N2 in FIG. 5. The first portion ND2a of the second node electrode can be inserted into a contact hole penetrating the inter-layer insulation layer ILD and the gate insulation layer GI, and can be connected to the source electrode SE1 of the first transistor T1. The first portion ND2a of the second node electrode can be inserted into a contact hole penetrating the inter-layer insulation layer ILD, the gate insulation layer GI, and the second buffer layer BF2 and can be connected to the second electrode Clb of the first capacitor C1. The second portion ND2b of the second node electrode can be disposed in the second source metal layer SDL2, can be inserted into a contact hole penetrating the first protection layer PLN1, and can be connected to the first portion ND2a of the second node electrode.

In FIG. 12, the second pixel electrode AE2 can be electrically connected to the pixel circuit disposed in the first direction DR1 of the pixel circuit illustrated in FIGS. 8 to 11. For example, the first pixel electrode AE1 can be connected to the first pixel SP1 configured to emit red light, and the second pixel electrode AE2 can be connected to the second pixel SP2 configured to emit green light. The light emitting diode ED which includes the second pixel electrode AE2 can emit light through a second light emitting region defined by the pixel defining layer.

In FIGS. 9 and 13, the first capacitor C1 can include the first electrode C1a and the second electrode C1b. The first electrode C1a of the first capacitor C1 can be disposed in the first light shielding layer LS1, and can overlap the second electrode C1b of the first capacitor C1. The first electrode C1a of the first capacitor C1 can be electrically connected to the gate electrode GE1 of the first transistor T1 through the first node electrode ND1. The second electrode C1b of the first capacitor C1 can be disposed in the second light shielding layer LS2, and can overlap the first electrode C1a of the first capacitor C1. The second electrode C1b of the first capacitor C1 can be electrically connected to the source electrode SE1 of the first transistor T1, the drain electrode DE3 of the third transistor T3, the drain electrode DE6 of the sixth transistor T6, and the first pixel electrode AE1 through the first portion ND2a and the second portion ND2b of the second node electrode.

The second transistor T2 can include a semiconductor region ACT2, the drain electrode DE2, the source electrode SE2, and the gate electrode GE2. The semiconductor region ACT2, the drain electrode DE2, and the source electrode SE2 of the second transistor T2 can be disposed in the active layer ACTL, and the gate electrode GE2 of the second transistor T2 can be disposed in the gate layer GTL. The gate electrode GE2 of the second transistor T2 can overlap the semiconductor region ACT2 of the second transistor T2. For example, the semiconductor region ACT2 of the second transistor T2 can include an oxide, and the drain electrode DE2 and the source electrode SE2 of the second transistor T2 can be n-type doped.

The gate electrode GE2 of the second transistor T2 can receive the first scan signal from the first scan line SCL1. The first scan line SCL1 can be disposed in the first source metal layer SDL1, and can extend in the first direction DR1. The gate electrode GE2 of the second transistor T2 can be integrally formed with the gate electrode GE4 of the fourth transistor T4. The drain electrode DE2 of the second transistor T2 can receive the data voltage from the data line DL. The drain electrode DE2 of the second transistor T2 can be electrically connected to the data line DL through the data connection electrode DNE disposed in the first source metal layer SDL1. The data line DL can be disposed in the second source metal layer SDL2, and can extend in the second direction DR2. The source electrode SE2 of the second transistor T2 can be integrally formed with the source electrode SE5 of the fifth transistor T5. The source electrode SE2 of the second transistor T2 can be electrically connected to the gate electrode GE1 of the first transistor T1 and the first electrode C1a of the first capacitor C1 through the first node electrode ND1.

The third transistor T3 can include a semiconductor region ACT3, the drain electrode DE3, the source electrode SE3, and the gate electrode GE3. The semiconductor region ACT3, the drain electrode DE3, and the source electrode SE3 of the third transistor T3 can be disposed in the active layer ACTL, and the gate electrode GE3 of the third transistor T3 can be disposed in the gate layer GTL. The gate electrode GE3 of the third transistor T3 can overlap the semiconductor region ACT3 of the third transistor T3. For example, the semiconductor region ACT3 of the third transistor T3 can include an oxide, and the drain electrode DE3 and the source electrode SE3 of the third transistor T3 can be n-type doped.

The gate electrode GE3 of the third transistor T3 can receive the second scan signal from the second scan line SCL2. The gate electrode GE3 of the third transistor T3 can be part of the second scan line SCL2. The second scan line SCL2 can be disposed in the gate layer GTL, and can extend in the first direction DR1. The drain electrode DE3 of the third transistor T3 can be integrally formed with the source electrode SE1 of the first transistor T1 and the drain electrode DE6 of the sixth transistor T6. The drain electrode DE3 of the third transistor T3 can be electrically connected to the second electrode C1b of the first capacitor C1 and the first pixel electrode AE1 of the light emitting diode ED through the first portion ND2a and the second portion ND2b of the second node electrode. The source electrode SE3 of the third transistor T3 can receive the initialization voltage Vint from the initialization voltage line VIL. The first initialization voltage line VIL1 can be inserted into a contact hole penetrating the inter-layer insulating layer ILD and the gate insulation layer GI, and can be connected to the source electrode SE3 of the third transistor T3.

The fourth transistor T4 can include the semiconductor region ACT4, the drain electrode DE4, the source electrode SE4, and the gate electrode GE4. The semiconductor region ACT4, the drain electrode DE4, and the source electrode SE4 of the fourth transistor T4 can be disposed in the active layer ACTL, and the gate electrode GE4 of the fourth transistor T4 can be disposed in the gate layer GTL. The gate electrode GE4 of the fourth transistor T4 can overlap the semiconductor region ACT4 of the fourth transistor T4. For example, the semiconductor region ACT4 of the fourth transistor T4 can include an oxide, and the drain electrode DE4 and the source electrode SE4 of the fourth transistor T4 can be n-type doped.

The gate electrode GE4 of the fourth transistor T4 can receive the first scan signal from the first scan line SCL1. The gate electrode GE4 of the fourth transistor T4 can be integrally formed with the gate electrode GE2 of the second transistor T2. The drain electrode DE4 of the fourth transistor T4 can receive the hold signal from the hold line HLD. The first hold line HLD1 can be inserted into a contact hole penetrating the inter-layer insulation layer ILD and the gate insulation layer GI, and can be connected to the drain electrode DE4 of the fourth transistor T4. The source electrode SE4 of the fourth transistor T4 can be integrally formed with the drain electrode DE1 of the first transistor T1. The source electrode SE4 of the fourth transistor T4 can be electrically connected to a gate electrode GE6 of the sixth transistor T6 and a third portion ND3c of a third node electrode disposed in the second source metal layer SDL2 through a second portion ND3b of the third node electrode disposed in the first source metal layer SDL1. The third portion ND3c of the third node electrode can be electrically connected to a gate electrode GE5 of the fifth transistor T5 and a first electrode C2a of the second capacitor through a first portion ND3a of the third node electrode disposed in the first source metal layer SDL1.

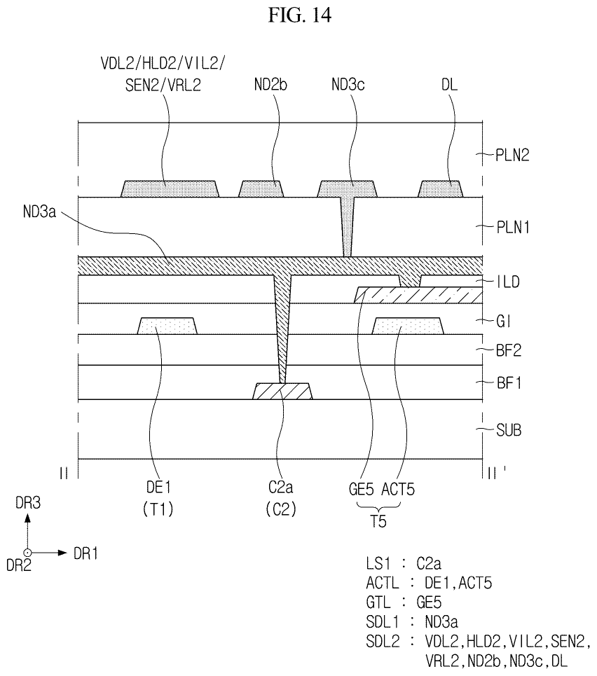

In FIGS. 11 and 14, the first to third portions ND3a, ND3b, and ND3c of the third node electrode can correspond to the third node N3 in FIG. 5. The first portion ND3a of the third node electrode can be inserted into a contact hole penetrating the inter-layer insulation layer ILD, and can be connected to the gate electrode GE5 of the fifth transistor T5. The first portion ND3a of the third node electrode can be inserted into a contact hole penetrating the inter-layer insulation layer ILD, the gate insulation layer GI, the second buffer layer BF2, and the first buffer layer BF1, and can be connected to the first electrode C2a of the second capacitor C2. The second portion ND3b of the third node electrode can be inserted into a contact hole penetrating the inter-layer insulation layer ILD and the gate insulation layer GI, and can be connected to the source electrode SE4 of the fourth transistor T4. The second portion ND3b of the third node electrode can be inserted into a contact hole penetrating the inter-layer insulation layer ILD, and can be connected to the gate electrode GE6 of the sixth transistor T6. An upper portion of the third portion ND3c of the third node electrode can be inserted into a contact hole penetrating the first protection layer PLN1, and can be connected to the first portion ND3a of the third node electrode disposed in the first source metal layer SDL1. A lower portion of the third node electrode can be inserted into a contact hole penetrating the first protection layer PLN1, and can be connected to the second portion ND3b of the third node electrode.

The second capacitor C2 can include the first electrode C2a and the second electrode C2b. The first electrode C2a of the second capacitor C2 can be disposed in the first light shielding layer LS1, and can overlap the second electrode C2b of the second capacitor C2. The first electrode C2a of the second capacitor C2 can be electrically connected to the source electrode SE4 of the fourth transistor T4, the gate electrode GE5 of the fifth transistor T5, and the gate electrode GE6 of the sixth transistor T6 through the first to third portions ND3a, ND3b, and ND3c of the third node electrode. The second electrode C2b of the second capacitor C2 can be disposed in the second light shielding layer LS2, and can overlap the first electrode C2a of the second capacitor C2. The second electrode C2b of the second capacitor C2 can be connected to the first reference voltage line VRL1 and can receive the reference voltage Vref.

The fifth transistor T5 can include a semiconductor region ACT5, the drain electrode DE5, the source electrode SE5, and the gate electrode GE5. The semiconductor region ACT5, the drain electrode DE5, and the source electrode SE5 of the fifth transistor T5 can be disposed in the active layer ACTL, and the gate electrode GE5 of the fifth transistor T5 can be disposed in the gate layer GTL. The gate electrode GE5 of the fifth transistor T5 can overlap the semiconductor region ACT5 of the fifth transistor T5. For example, the semiconductor region ACT5 of the fifth transistor T5 can include an oxide, and the drain electrode DE5 and the source electrode SE5 of the fifth transistor T5 can be n-type doped.

The gate electrode GE5 of the fifth transistor T5 can be electrically connected to the source electrode SE4 of the fourth transistor T4, the gate electrode GE6 of the sixth transistor T6, and the first electrode C2a of the second capacitor C2 through the first to third portions ND3a, ND3b, and ND3c of the third node electrode. The drain electrode DE5 of the fifth transistor T5 can receive the reference voltage Vref from the reference voltage line VRL. The first reference voltage line VRL1 can be inserted into a contact hole penetrating the inter-layer insulation layer ILD and the gate insulation layer GI, and can be connected to the drain electrode DE5 of the fifth transistor T5. The source electrode SE5 of the fifth transistor T5 can be electrically connected to the gate electrode GE1 of the first transistor T1, the first electrode C1a of the first capacitor C1, and the source electrode SE2 of the second transistor T2 through the first node electrode ND1.

The sixth transistor T6 can include a semiconductor region ACT6, the drain electrode DE6, the source electrode SE6, and the gate electrode GE6. The semiconductor region ACT6, the drain electrode DE6, and the source electrode SE6 of the sixth transistor T6 can be disposed in the active layer ACTL, and the gate electrode GE6 of the sixth transistor T6 can be disposed in the gate layer GTL. The gate electrode GE6 of the sixth transistor T6 can overlap the semiconductor region ACT6 of the sixth transistor T6. For example, the semiconductor region ACT6 of the sixth transistor T6 can include an oxide, and the drain electrode DE6 and the source electrode SE6 of the sixth transistor T6 can be n-type doped.

The gate electrode GE6 of the sixth transistor T6 can be electrically connected to the source electrode SE4 of the fourth transistor T4, the gate electrode GE5 of the fifth transistor T5, and the first electrode C2a of the second capacitor C2 through the first to third portions ND3a, ND3b, and ND3c of the third node electrode. The drain electrode DE6 of the sixth transistor T6 can be integrally formed with the source electrode SE1 of the first transistor T1 and the drain electrode DE3 of the third transistor T3. The drain electrode DE6 of the sixth transistor T6 can be electrically connected to the second electrode C1b of the first capacitor C1 and the first pixel electrode AE1 of the light emitting diode ED through the first and second portions ND2a and ND2b of the second node electrode. The source electrode SE6 of the sixth transistor T6 can be electrically connected to the second sensing line SEN2 through the sensing connection electrode SNE disposed in the first source metal layer SDL1.

The display device 10 according to various embodiments of the present disclosure can be described as below.

One or more embodiments of the present disclosure provide a display device, including: a substrate; a first light shielding layer disposed on the substrate; a second light shielding layer disposed on the first light shielding layer; an active layer disposed on the second light shielding layer and including a semiconductor region of a first transistor; a gate layer including a gate electrode of the first transistor disposed on the active layer; a first source metal layer including a first hold line disposed on the gate layer, extending in a first direction and configured to supply a hold signal; a second source metal layer including a second hold line disposed on the first source metal layer, extending in a second direction intersecting the first direction and connected to the first hold line; a light emitting element including a pixel electrode disposed on the second source metal layer; a second transistor configured to supply a data voltage to a first node which is a gate electrode of the first transistor based on a first scan signal; a third transistor configured to supply an initialization voltage to a second node which is a source electrode of the first transistor based on a second scan signal; a fourth transistor configured to supply the hold signal to a third node based on the first scan signal; a fifth transistor electrically connecting a reference voltage line and the first node based on a voltage of the third node; and a sixth transistor electrically connecting the second node and a sensing line based on a voltage of the third node.

In the display device according to various embodiments of the present disclosure, the sensing line can include a first sensing line disposed in the first light shielding layer and extending in the first direction; and a second sensing line disposed in the second source metal layer, extending in the second direction and connected to the first sensing line, and the display device can further include a sensing connection electrode disposed on the first source metal layer and electrically connecting the first sensing line and a source electrode of the sixth transistor.

In the display device according to various embodiments of the present disclosure, the display device can further include a first initialization voltage line disposed in the first source metal layer, extending in the first direction and configured to supply the initialization voltage to a source electrode of the third transistor; and a second initialization voltage line disposed in the second source metal layer, extending in the second direction and connected to the first initialization voltage line.

In the display device according to various embodiments of the present disclosure, the display device can further include a first driving voltage line disposed in the first source metal layer, extending in the first direction and configured to supply a driving voltage to a drain electrode of the first transistor; and a second driving voltage line disposed in the second source metal layer, extending in the second direction and connected to the first driving voltage line.

In the display device according to various embodiments of the present disclosure, the display device can further include a first electrode of a first capacitor disposed in the first light shielding layer and electrically connected to the first node; and a second electrode of the first capacitor disposed in the second light shielding layer and electrically connected to the second node.

In the display device according to various embodiments of the present disclosure, the display device can further include a first node electrode disposed in the first source metal layer and electrically connecting the gate electrode of the first transistor, the first electrode of the first capacitor, and a source electrode of the second transistor.

In the display device according to various embodiments of the present disclosure, the display device can further include a first portion of a second node electrode disposed in the first source metal layer and connected to the source electrode of the first transistor and the second electrode of the first capacitor; and a second portion of the second node electrode disposed in the second source metal layer and electrically connecting the first portion of the second node electrode and the pixel electrode.

In the display device according to various embodiments of the present disclosure, the display device can further include a first electrode of a second capacitor disposed in the first light shielding layer and electrically connected to the third node; and a second electrode of the second capacitor disposed in the second light shielding layer and electrically connected to the reference voltage line.

In the display device according to various embodiments of the present disclosure, the reference voltage line can include a first reference voltage line disposed in the first source metal layer, extending in the first direction and configured to supply a reference voltage to a drain electrode of the fifth transistor and the second electrode of the second capacitor; and a second reference voltage line disposed in the second source metal layer, extending in the second direction and connected to the first reference voltage line.

In the display device according to various embodiments of the present disclosure, the display device can further include a first portion of a third node electrode disposed in the first source metal layer, extending in the first direction and connected to the first electrode of the second capacitor and a gate electrode of the fifth transistor; a second portion of the third node electrode disposed in the first source metal layer and connected to a source electrode of the fourth transistor and a gate electrode of the sixth transistor; and a third portion of the third node electrode disposed in the second source metal layer and electrically connecting the first portion and the second portion of the third node electrode.

In the display device according to various embodiments of the present disclosure, the display device can further include a first scan line disposed in the first source metal layer, extending in the first direction, and configured to supply the first scan signal to a gate electrode of the second transistor and a gate electrode of the fourth transistor; and a second scan line disposed in the gate layer, extending in the first direction and configured to supply the second scan signal to a gate electrode of the third transistor.

In the display device according to various embodiments of the present disclosure, the display device can further include a data line disposed in the second source metal layer, extending in the second direction and configured to supply the data voltage; and a data connection electrode disposed in the first source metal layer and electrically connecting the data line and a drain electrode of the second transistor.

Another embodiment of the present disclosure provide a display device, including: a substrate; a first light shielding layer disposed on the substrate; a second light shielding layer disposed on the first light shielding layer; an active layer disposed on the second light shielding layer and including a semiconductor region of a first transistor; a gate layer including a gate electrode of the first transistor disposed on the active layer; a first source metal layer including a first sensing line disposed on the gate layer, extending in a first direction and configured to supply a sensing signal; a second source metal layer including a second sensing line disposed on the first source metal layer, extending in a second direction intersecting the first direction and connected to the first sensing line; a light emitting element including a pixel electrode disposed on the second source metal layer; a second transistor configured to supply a data voltage to a first node which is a gate electrode of the first transistor based on a first scan signal; a third transistor configured to supply an initialization voltage to a second node which is a source electrode of the first transistor based on a second scan signal; a fourth transistor configured to supply a hold signal to a third node based on the first scan signal; a fifth transistor electrically connecting a reference voltage line and the first node based on a voltage of the third node; and a sixth transistor electrically connecting the second node and the first sensing line based on a voltage of the third node.

In a display device according to various embodiments of the present disclosure, the display device can further include a first electrode of a first capacitor disposed in the first light shielding layer and electrically connected to the first node; and a second electrode of the first capacitor disposed in the second light shielding layer and electrically connected to the second node.

In the display device according to various embodiments of the present disclosure, the display device can further include a first node electrode disposed in the first source metal layer and electrically connecting the gate electrode of the first transistor, the first electrode of the first capacitor, and a source electrode of the second transistor.

In the display device according to various embodiments of the present disclosure, the display device can further include a first portion of a second node electrode disposed in the first source metal layer and connected to the source electrode of the first transistor and the second electrode of the first capacitor; and a second portion of the second node electrode disposed in the second source metal layer and electrically connecting the first portion of the second node electrode and the pixel electrode.

In the display device according to various embodiments of the present disclosure, the display device can further include a first electrode of a second capacitor disposed in the first light shielding layer and electrically connected to the third node; and a second electrode of the second capacitor disposed in the second light shielding layer and electrically connected to the reference voltage line.

In the display device according to various embodiments of the present disclosure, the display device can further include a first portion of a third node electrode disposed in the first source metal layer, extending in the first direction and connected to the first electrode of the second capacitor and a gate electrode of the fifth transistor; a second portion of the third node electrode disposed in the first source metal layer and connected to a source electrode of the fourth transistor and a gate electrode of the sixth transistor; and a third portion of the third node electrode disposed in the second source metal layer and electrically connecting the first portion and the second portion of the third node electrode.

In the display device according to various embodiments of the present disclosure, the reference voltage line can include a first reference voltage line disposed in the first source metal layer, extending in the first direction and configured to supply a reference voltage to a drain electrode of the fifth transistor and the second electrode of the second capacitor; and a second reference voltage line disposed in the second source metal layer, extending in the second direction and connected to the first reference voltage line.

In the display device according to various embodiments of the present disclosure, the display device can further include a first hold line disposed in the first source metal layer, extending in the first direction and configured to supply the hold signal to a drain electrode of the fourth transistor; and a second hold line disposed in the second source metal layer, extending in the second direction and connected to the first sensing line.

The present disclosure has been described in more detail with reference to the example embodiments, but the present disclosure is not limited to the example embodiments. It will be apparent to those skilled in the art that various modifications can be made without departing from the technical sprit of the disclosure. Accordingly, the example embodiments disclosed in the present disclosure are used not to limit but to describe the technical spirit of the present disclosure, and the technical spirit of the present disclosure is not limited to the example embodiments. Therefore, the example embodiments described above are considered in all respects to be illustrative and not restrictive. The protection scope of the present disclosure must be interpreted by the appended claims and it should be interpreted that all technical spirits within a scope equivalent thereto are included in the appended claims of the present disclosure.

REFERENCE NUMERALS

| | |
|---|---|
| 10: display device | 100: display panel |
| 200: display driver | 220: scan driver |
| 500: timing controller | 600: power supply |
| 700: memory | UP: unit pixel |
| SP1, SP2, SP3: first to third pixels | |
| T1, T2, T3, T4, T5, T6: first to sixth transistors | |
| C1, C2: first and second capacitors | |
| ED: light emitting diode | |

What is claimed is:

1. A display device, comprising:
a substrate;
a first light shielding layer disposed on the substrate;
a second light shielding layer disposed on the first light shielding layer;
an active layer disposed on the second light shielding layer and including a semiconductor region of a first transistor;
a gate layer including a gate electrode of the first transistor disposed on the active layer;
a first source metal layer including a first hold line disposed on the gate layer, the first source metal layer extending in a first direction and configured to supply a hold signal;
a second source metal layer including a second hold line disposed on the first source metal layer, the second source metal layer extending in a second direction intersecting the first direction and connected to the first hold line;
a light emitting element including a pixel electrode disposed on the second source metal layer;
a second transistor configured to supply a data voltage to a first node being at a gate electrode of the first transistor, based on a first scan signal;
a third transistor configured to supply an initialization voltage to a second node being at a source electrode of the first transistor, based on a second scan signal;
a fourth transistor configured to supply the hold signal to a third node based on the first scan signal;
a fifth transistor electrically connecting a reference voltage line and the first node based on a voltage of the third node; and
a sixth transistor electrically connecting the second node and a sensing line based on a voltage of the third node.

2. The display device of claim 1,
wherein the sensing line comprises:
a first sensing line disposed in the first light shielding layer and extending in the first direction; and
a second sensing line disposed in the second source metal layer, the second sensing line extending in the second direction and connected to the first sensing line, and
wherein the display device further comprises:
a sensing connection electrode disposed in the first source metal layer and electrically connecting the first sensing line and a source electrode of the sixth transistor.

3. The display device of claim 1, further comprising:
a first initialization voltage line disposed in the first source metal layer, the first initialization voltage line extending in the first direction and configured to supply the initialization voltage to a source electrode of the third transistor; and
a second initialization voltage line disposed in the second source metal layer, the second initialization voltage line extending in the second direction and connected to the first initialization voltage line.

4. The display device of claim 1, further comprising:
a first driving voltage line disposed in the first source metal layer, the first driving voltage line extending in the first direction and configured to supply a driving voltage to a drain electrode of the first transistor; and
a second driving voltage line disposed in the second source metal layer, the second driving voltage line extending in the second direction and connected to the first driving voltage line.

5. The display device of claim 1, further comprising:
a first electrode of a first capacitor disposed in the first light shielding layer and electrically connected to the first node; and
a second electrode of the first capacitor disposed in the second light shielding layer and electrically connected to the second node.

6. The display device of claim 5, further comprising:
a first node electrode disposed in the first source metal layer and electrically connecting the gate electrode of the first transistor, the first electrode of the first capacitor, and a source electrode of the second transistor.

7. The display device of claim 5, further comprising:
a first portion of a second node electrode disposed in the first source metal layer and connected to the source electrode of the first transistor and the second electrode of the first capacitor; and
a second portion of the second node electrode disposed in the second source metal layer and electrically connecting the first portion of the second node electrode and the pixel electrode.

8. The display device of claim 1, further comprising:
a first electrode of a second capacitor disposed in the first light shielding layer and electrically connected to the third node; and
a second electrode of the second capacitor disposed in the second light shielding layer and electrically connected to the reference voltage line.

9. The display device of claim 8,
wherein the reference voltage line comprises:
a first reference voltage line disposed in the first source metal layer, the first reference voltage line extending in the first direction and configured to supply a reference voltage to a drain electrode of the fifth transistor and the second electrode of the second capacitor; and
a second reference voltage line disposed in the second source metal layer, the second reference voltage line extending in the second direction and connected to the first reference voltage line.

10. The display device of claim 8, further comprising:
a first portion of a third node electrode disposed in the first source metal layer, the first portion of the third node electrode extending in the first direction and connected to the first electrode of the second capacitor and a gate electrode of the fifth transistor;
a second portion of the third node electrode disposed in the first source metal layer and connected to a source electrode of the fourth transistor and a gate electrode of the sixth transistor; and
a third portion of the third node electrode disposed in the second source metal layer and electrically connecting the first portion and the second portion of the third node electrode.

11. The display device of claim 1, further comprising:
a first scan line disposed in the first source metal layer, the first scan line extending in the first direction and configured to supply the first scan signal to a gate electrode of the second transistor and a gate electrode of the fourth transistor; and
a second scan line disposed in the gate layer, the second scan line extending in the first direction and configured to supply the second scan signal to a gate electrode of the third transistor.

12. The display device of claim 1, further comprising:
a data line disposed in the second source metal layer, the data line extending in the second direction and configured to supply the data voltage; and
a data connection electrode disposed in the first source metal layer and electrically connecting the data line and a drain electrode of the second transistor.

13. A display device, comprising:
a first light shielding layer disposed on a substrate;
a second light shielding layer disposed on the first light shielding layer;
an active layer disposed on the second light shielding layer and including a semiconductor region of a first transistor;
a gate layer including a gate electrode of the first transistor disposed on the active layer;
a first source metal layer including a first sensing line disposed on the gate layer, the first source metal layer extending in a first direction and configured to supply a sensing signal;
a second source metal layer including a second sensing line disposed on the first source metal layer, the second source metal layer extending in a second direction intersecting the first direction and connected to the first sensing line;
a light emitting element including a pixel electrode disposed on the second source metal layer;
a second transistor configured to supply a data voltage to a first node being at a gate electrode of the first transistor, based on a first scan signal;
a third transistor configured to supply an initialization voltage to a second node being at a source electrode of the first transistor, based on a second scan signal;
a fourth transistor configured to supply a hold signal to a third node based on the first scan signal;
a fifth transistor electrically connecting a reference voltage line and the first node based on a voltage of the third node; and
a sixth transistor electrically connecting the second node and the first sensing line based on a voltage of the third node.

14. The display device of claim 13, further comprising:
a first electrode of a first capacitor disposed in the first light shielding layer and electrically connected to the first node; and
a second electrode of the first capacitor disposed in the second light shielding layer and electrically connected to the second node.

15. The display device of claim 14, further comprising:
a first node electrode disposed in the first source metal layer and electrically connecting the gate electrode of the first transistor, the first electrode of the first capacitor, and a source electrode of the second transistor.

16. The display device of claim 14, further comprising:
a first portion of a second node electrode disposed in the first source metal layer and connected to the source electrode of the first transistor and the second electrode of the first capacitor; and
a second portion of the second node electrode disposed in the second source metal layer and electrically connecting the first portion of the second node electrode and the pixel electrode.

17. The display device of claim 13, further comprising:
a first electrode of a second capacitor disposed in the first light shielding layer and electrically connected to the third node; and
a second electrode of the second capacitor disposed in the second light shielding layer and electrically connected to the reference voltage line.

18. The display device of claim 17, further comprising:
a first portion of a third node electrode disposed in the first source metal layer, the first portion of the third node electrode extending in the first direction and connected to the first electrode of the second capacitor and a gate electrode of the fifth transistor;
a second portion of the third node electrode disposed in the first source metal layer and connected to a source electrode of the fourth transistor and a gate electrode of the sixth transistor; and
a third portion of the third node electrode disposed in the second source metal layer and electrically connecting the first portion and the second portion of the third node electrode.

19. The display device of claim 17,
wherein the reference voltage line includes:
a first reference voltage line disposed in the first source metal layer, the first reference voltage line extending in the first direction and configured to supply a reference voltage to a drain electrode of the fifth transistor and the second electrode of the second capacitor; and
a second reference voltage line disposed in the second source metal layer, the second reference voltage line extending in the second direction and connected to the first reference voltage line.

20. The display device of claim 13, further comprising:
a first hold line disposed in the first source metal layer, the first hold line extending in the first direction and configured to supply the hold signal to a drain electrode of the fourth transistor; and
a second hold line disposed in the second source metal layer, the first hold line extending in the second direction and connected to the first sensing line.
